(19) United States
(12) Patent Application Publication
(10) Pub. No.: US 2009/0107549 A1
(43) Pub. Date: Apr. 30, 2009

(54) PERCOLATING AMORPHOUS SILICON SOLAR CELL

(76) Inventor: PETER BORDEN, San Mateo, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/923,406

(22) Filed: Oct. 24, 2007

(51) Int. Cl. H01L 31/00; B05D 5/12

(52) U.S. Cl. 136/261; 427/74

(57) ABSTRACT

The present invention generally comprises a solar cell and a solar cell fabrication process. Photogenerated electrons and electron-holes may have a short lifetime or low mobility that permits the electrons or electron-holes to recombine before reaching the junction. A percolating solar cell device may shorten the distance that the electrons and electron-holes need to travel to reach the junction. The percolating solar cell may be formed by depositing a silicon containing layer with poragens and then decomposing the poragens to create openings such as pores in the silicon containing layer. In one embodiment, the silicon containing layer is deposited and then etched anodically to create openings in the silicon containing layer. The layer deposited over the silicon containing layer may extend into the openings. By extending into the openings, the distance to the junction for electrons and electron-holes may be reduced and more electrons and electron-holes may reach the junction.

### BACKGROUND OF THE INVENTION

1. Field of the Invention

Embodiments of the present invention generally relate to a solar cell and a solar cell fabrication process.

2. Description of the Related Art

The ability to collect photogenerated electrons and electron-holes is one of the chief limiters to the performance of solar cells, especially solar cells made with short lifetime or low mobility materials. As shown in FIG. 1, a conventional solar cell 100 has a planar structure that consists of a p-n junction with an n-type semiconductor layer 104 over a p-type semiconductor layer 102. An absorbed photon forms an electron/electron-hole pair. In the p-type semiconductor layer 102, the electron 106 is the minority. In the n-type semiconductor layer 104, the electron-hole 108 is the minority carrier. The minority carrier must diffuse to the junction, where it is swept across to form the photocurrent. If the carrier recombines before reaching the junction 110, it is lost. Therefore, the layers must be thin compared to the diffusion length, given by L²=(kT/q)μτ, where k is Boltzmann's constant, T is temperature, q is the electron charge, μ is the mobility, and T is the lifetime. When the mobility or lifetime is small, L may be shorter than the distance required to effectively absorb light. In that case, carriers will be lost before they are collected and the cell will have less than ideal efficiency.

As shown in FIG. 1, the electrons 106 may have to travel a short distance as shown by arrows C, a medium distance as shown by arrows B, or a long distance as shown by arrows A. Similarly, the electron-holes 108 may have to travel a short distance as shown by arrows D, a medium distance as shown by arrows E, or a long distance as shown by arrows F. The longer the distance of travel, the greater the likelihood that the electron-holes 108 or electrons 106 will recombine before reaching the junction 110.

Organic solar cells having percolating structures with improved efficiency are formed by spin coating a first layer such as poly(3,4-ethylene-dioxythiophene) doped poly(styrene sulfonic acid) onto a substrate and then depositing a blended composition of poly[2-methoxy-5-(3′,7′-dimethyloctyloxy)-1,4-phenylene vinylene] (MDMO-PPV) and [6,6]-phenyl-C61-butyric acid methyl ester (PCBM). The blended composition of MDMO-PPV and PCBM is a percolated layer which improves carrier transport properties, but blended compositions have power efficiencies well below 5 percent.

Silicon based solar cells, on the other hand, have higher power efficiencies than organic solar cells, but still have power efficiencies of only about 25 percent because of long paths for electrons and electron-holes to travel to reach the junction. It would be beneficial to increase the power efficiency of solar cells by shortening the path for electrons and electron-holes to travel to the junction. Therefore, there is a need in the art for a solar cell having a shorter path for electrons and electron-holes to travel to reach the junction.

### SUMMARY OF THE INVENTION

The present invention generally comprises a solar cell and a solar cell fabrication process. Photogenerated electrons and electron-holes may have a short lifetime or low mobility that permits the electrons or electron-holes to recombine before reaching the junction. A percolating solar cell device may shorten the distance that the electrons and electron-holes need to travel to reach the junction. The percolating solar cell may be formed by depositing a silicon containing layer with poragens and then decomposing the poragens to create openings such as pores in the silicon containing layer. In one embodiment, the silicon containing layer is deposited and then etched anodically to create openings in the silicon containing layer. The layer deposited over the silicon containing layer may extend into the openings. By extending into the openings, the distance to the junction for electrons and electron-holes may be reduced and more electrons and electron-holes may reach the junction.

In one embodiment, a solar cell fabrication process comprises forming a first silicon containing layer over a solar cell substrate, the first silicon containing layer having one or more openings therein, and forming a second silicon containing layer over the first silicon containing layer, the second silicon containing layer extending into at least one opening of the first silicon containing layer.

In another embodiment, a solar cell fabrication process comprises depositing a p-doped silicon layer over a solar cell substrate, depositing a second layer on the p-doped silicon layer, and creating an uneven interface between the p-doped silicon layer and the second layer such that the second layer extends at least partially into the p-doped silicon layer.

In another embodiment, a solar cell comprises a first silicon containing layer disposed over a solar cell substrate, a second silicon containing layer coupled with the first silicon containing layer, and an interface between the first silicon containing layer and the second silicon containing layer is uneven such that the second silicon containing layer extends at least partially into the first silicon containing layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross sectional view of a solar cell.

FIG. 2 is a schematic cross sectional view of a solar cell having a percolated layer.

FIG. 3 is a flow chart of a process for forming a solar cell according to one embodiment of the invention.

FIGS. 4A-4D are schematic cross sectional views of a solar cell at various stages of production according to the embodiment shown in FIG. 3.

FIG. 5 is a flow chart of a process for forming a solar cell according to another embodiment of the invention.

FIGS. 6A-6C are schematic cross sectional views of a solar cell at various stages of production according to the embodiment shown in FIG. 5.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally comprises a solar cell and a solar cell fabrication process. Photogenerated electrons and electron-holes may have a short lifetime or low mobility that permits the electrons or electron-holes to recombine before reaching the junction. A percolating solar cell device may shorten the distance that the electrons and electron-holes need to travel to reach the junction. The percolating solar cell may be formed by depositing a silicon containing layer with poragens and then decomposing the poragens to create pores or openings in the silicon containing layer. In one embodiment, the silicon containing layer is deposited and then etched anodically to create pores or openings in the silicon containing layer. The layer deposited over the silicon containing layer may extend into the pores or openings. By extending into the pores or openings, the distance to the junction for electrons and electron-holes may be reduced and more electrons and electron-holes may reach the junction.

As used throughout the specification, the terms “porosity”, “porous” and “porous layer” are used to describe examples of openings. It is to be understood that a “porous layer” or a layer that is “porous” or a layer having a “porosity” is a layer that comprises a plurality of pores.

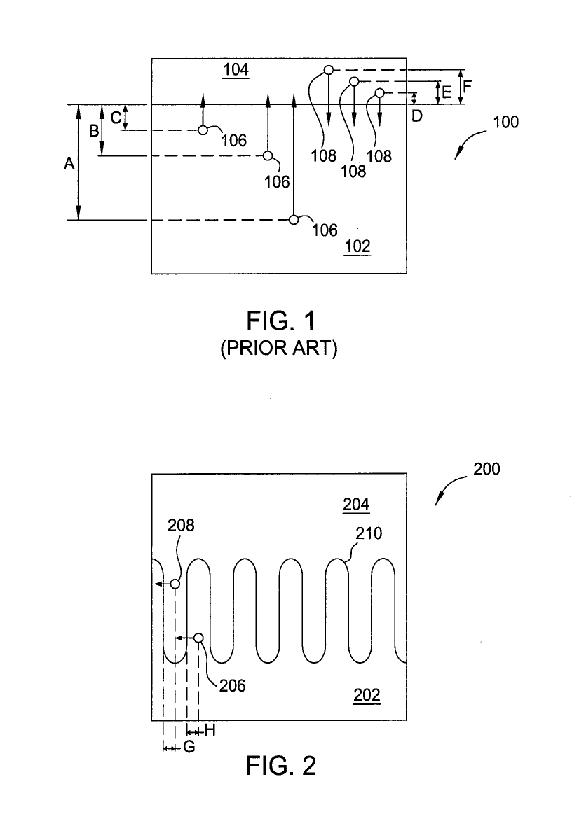

FIG. 2 is a schematic cross sectional view of a solar cell 200 having a percolated layer. The solar cell 200 comprises a first layer 202 and a second layer 204. The first layer 202 may comprise a silicon containing material such as amorphous silicon, microcrystalline silicon, polysilicon, thin film silicon, p-doped silicon, or intrinsic silicon. The second layer 204 may comprise a silicon containing material such as amorphous silicon, microcrystalline silicon, polysilicon, thin film silicon, n-doped silicon, or intrinsic silicon. The junction 210 between the first layer 202 and the second layer 204 has a percolating structure. The percolating structure shortens the distance (represented by arrows G) that an electron-hole 208 needs to travel to reach the junction 210 compared to a conventional, planar solar cell. The percolating structure also shortens the distance (represented by arrows H) that an electron 206 needs to travel to reach the junction 210 compared to a conventional, planar solar cell. In other words, the percolating structure will reduce the amount of electrons 206 and electron-holes 208 that need to travel the long distance A or F shown in FIG. 1 and increase the number of electrons 206 and electron-holes 208 that need to travel a short distance. In one embodiment, the percolating structure may be formed by decomposing poragens deposited with the first layer 202. In another embodiment, the percolating structure may be formed by anodically etching the first layer 202. Non-percolating regions sandwich the percolating layer so that contact can be made to n-type and p-type regions without forming a short circuit.

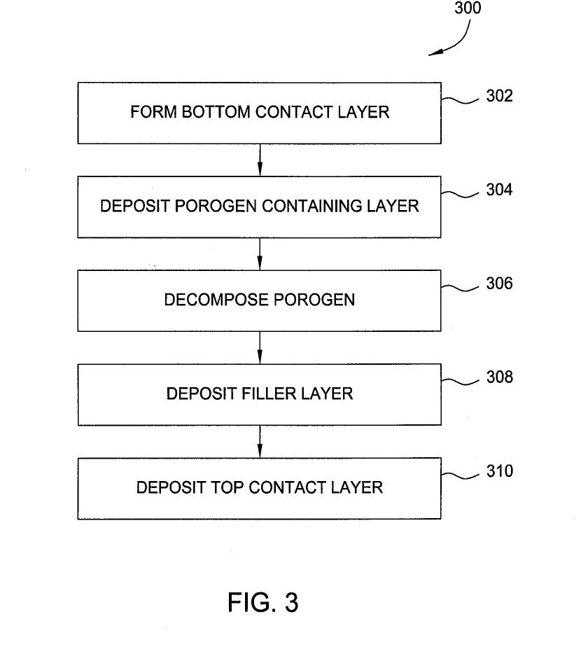

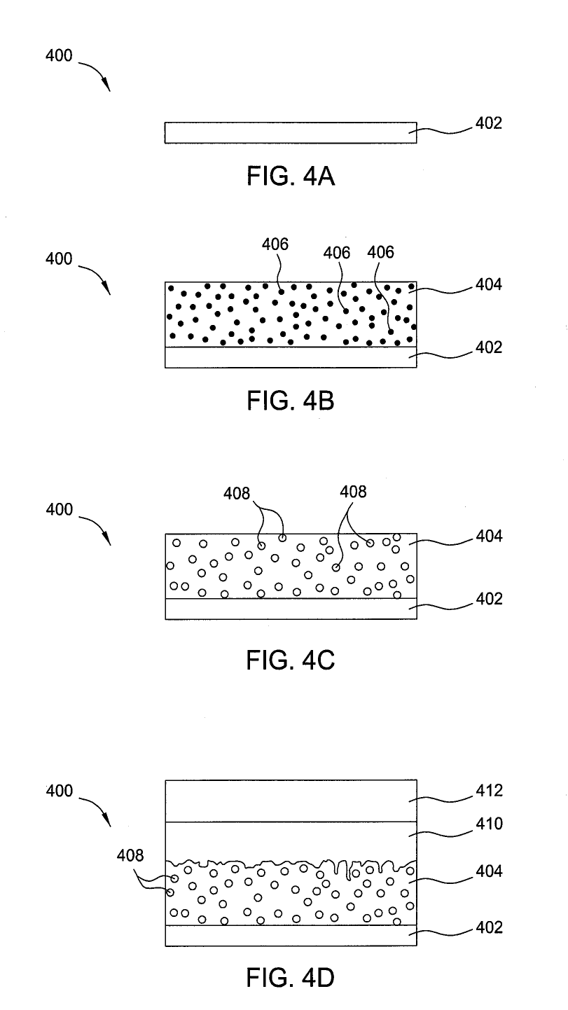

FIG. 3 is a flow chart 300 of a process for forming a solar cell according to one embodiment of the invention. FIGS. 4A-4D are schematic cross sectional views of a solar cell 400 at various stages of production according to the embodiment shown in FIG. 3. As shown in FIG. 4A, a bottom contact layer 402 is formed (Step 302). The contact layer 402 may comprise a uniform layer of a single conductivity type such as p-type (i.e., p-doped). The contact layer 402 may be formed by conventional deposition methods such as chemical vapor deposition (CVD), plasma enhanced chemical vapor deposition (PECVD), atomic layer deposition (ALD), and physical vapor deposition (PVD). Exemplary chambers in which the process may be performed include a PECVD chamber available from Applied Materials, Inc., Santa Clara, Calif. It is to be understood that the invention may be practiced in other chambers produced by other manufacturers.

As shown in FIG. 4B, a first layer 404 may then be deposited over the contact layer 402 (Step 304). The first layer 404 may be formed by conventional deposition methods such as CVD, PECVD, ALD, and PVD. The first layer 404 may be an intrinsic layer or a layer of the same conductivity type as the contact layer 402. The first layer 404 may comprise a silicon containing material such as amorphous silicon, microcrystalline silicon, polysilicon, thin film silicon, p-doped silicon, or intrinsic silicon. The first layer 404 may be deposited with poragens 406 dispersed throughout. The poragens 406 may be selected from the group consisting of ethylene, propylene, isobutylene, acetylene, allylene, ethylacetylene, 1,3-butadiene, isoprene, 2,3-dimethyl-1,3-butadiene, alpha-terpinine, piperylene, and combinations thereof. In general, the poragens are materials, most commonly organic, that form inclusions in a deposited layer and decompose into a gaseous form when the layer is exposed to ultraviolet light, elevated temperature or appropriate process gases. Amorphous silicon recrystallizes at elevated temperature. Thus, then the percolated layer is amorphous silicon, the decomposition may occur below the temperature at which amorphous silicon recrystallizes. In one embodiment, the temperature may be below about 600 degrees Celsius. The poragens 406 may be inert relative to the first layer 404 such that the poragens 406 do not react with the first layer 404 to change the desired characteristics of the first layer 404. In one embodiment, the poragens 406 may be selected to selectively react with the first layer 404 such that the characteristics of the first layer 404 may be influenced by the poragens 406 to tailor the first layer 404 to the desired characteristics. In one embodiment, the contact layer 402 and the first layer 404 are deposited as a single layer. In another embodiment, the contact layer 402 and the first layer 404 are separate layers. In one embodiment, the poragens 406 may have a diameter of about 20 Angstroms to about 50 Angstroms.

In one embodiment, the first layer 404 and the poragens 406 may be deposited by CVD where a silicon containing gas and a poragen forming gas are simultaneously fed to a processing chamber to deposit a silicon containing first layer 404 having poragens 406 dispersed therein.

As shown in FIG. 4C, the poragens 406 may be decomposed (Step 306) to leave pores 408 in place of the poragens 406. The poragens 406 may be decomposed by UV treating the first layer 404 or thermally treating the first layer 404 to drive of the poragens. The thermal treatment may comprise heating the first layer 404 to a temperature between about 400 degrees Celsius and about 500 degrees Celsius. In one embodiment, the first layer 404 may be heated to a temperature between about 440 degrees Celsius and about 460 degrees Celsius. In some cases, it may additionally be desirable to add a process gas such as oxygen or hydrogen to further accelerate decomposition. Oxygen may form a thin oxide layer, but the thin oxide layer will not degrade performance as carriers may tunnel through the oxide layer.

As shown in FIG. 4D, a filler or second layer 410 may be deposited over the first layer 404 (Step 308). The second layer 410 may be formed by conventional deposition methods such as CVD, PECVD, ALD, and PVD. The filler or second layer 410 may comprise a silicon containing material such as amorphous silicon, microcrystalline silicon, polysilicon, thin film silicon, n-doped silicon, or intrinsic silicon. In one embodiment, the second layer 410 is an intrinsic layer. In another embodiment, the second layer 410 comprises an n-doped layer. The second layer 410 fills in the pores 408 that are on the surface of the first layer 404. Additionally, the second layer 410 may fill in any pores 408 that are connected with the pores 408 that are on the surface of the first layer 404. In one embodiment, the second layer 410 may be deposited by CVD. The conformal growth of CVD permits the second layer 410 to fill the pores 408 of the first layer 404. Thus, a percolating structure is formed. A top contact layer 412 may be deposited over the second layer 410. The top contact layer 412 may be deposited in a manner similar to the contact layer 402 (Step 310). The contact layer 412 may comprise a uniform layer of a single conductivity type such as n-type (i.e., n-doped).

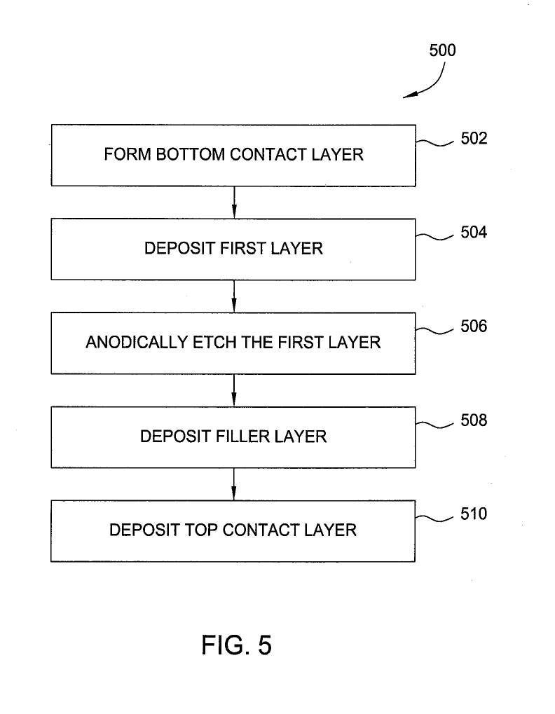

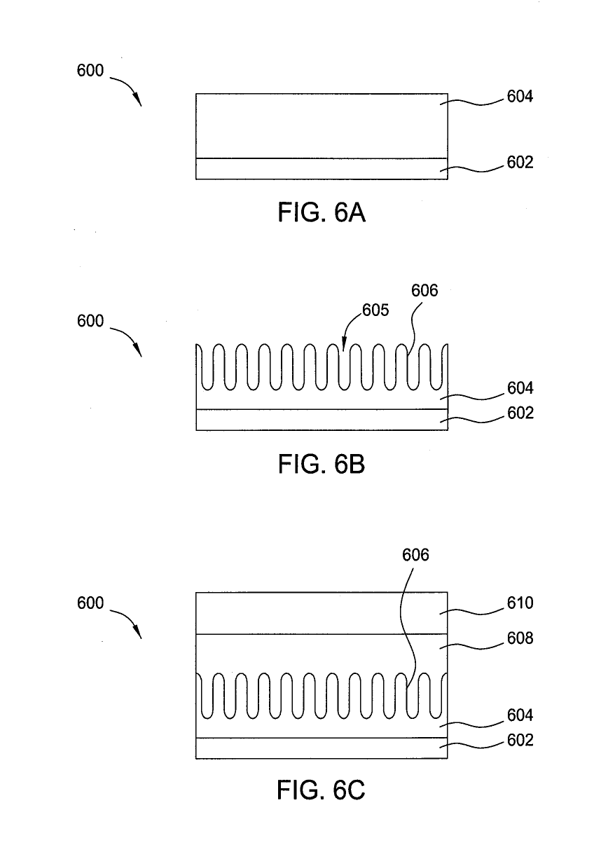

FIG. 5 is a flow chart 500 of a process for forming a solar cell according to another embodiment of the invention. FIGS. 6A-6C are schematic cross sectional views of a solar cell 600 at various stages of production according to the embodiment shown in FIG. 5. As shown in FIG. 6A, a bottom contact layer 602 is formed (Step 502). The contact layer 602 may comprise a uniform layer of a single conductivity type such as p-type (i.e., p-doped). The contact layer 602 may be formed by conventional deposition methods such as CVD, PECVD, ALD, and PVD. A first layer 604 may then be deposited over the contact layer 602 (Step 504).

The first layer 604 may be formed by conventional deposition methods such as CVD, PECVD, ALD, and PVD. The first layer 604 may be an intrinsic layer or a layer of the same conductivity type as the contact layer 602. The first layer 604 may comprise a silicon containing material such as amorphous silicon, microcrystalline silicon, polysilicon, thin film silicon, p-doped silicon, or intrinsic silicon.

As shown in FIG. 6B, after the first layer 604 has been deposited, the first layer may be anodically etched (Step 506) to form pores or channels 605 within the first layer 604. The pores or channels 605 may have a width between about 0.005 microns and about 0.015 microns. The first layer 604 may be anodically etched in a polytrifluorochloroethylene cell with nitrogen circulation under potentiostatic conditions. An electrolyte of hydrogen fluoride and ammonia chloride may be introduced into the cell to anodically etch the first layer 604.

As shown in FIG. 6C, a filler or second layer 608 may be deposited over the first layer 608 (Step 508). The second layer 608 may be formed by conventional deposition methods such as CVD, PECVD, ALD, and PVD. The filler or second layer 608 may comprise a silicon containing material such as amorphous silicon, microcrystalline silicon, polysilicon, thin film silicon, n-doped silicon, or intrinsic silicon. In one embodiment, the second layer 608 is an intrinsic layer. In another embodiment, the second layer 608 comprises an n-doped layer. The second layer 608 fills in the channels 605 in the first layer 604. In one embodiment, the second layer 608 may be deposited by CVD. The conformal growth of CVD permits the second layer 608 to fill the channels 605 of the first layer 604. Thus, a percolating structure is formed. A top contact layer 610 may be deposited over the second layer 608. The top contact layer 610 may be deposited in a manner similar to the contact layer 602 (Step 510). The contact layer 610 may comprise a uniform layer of a single conductivity type such as n-type (i.e., n-doped).

Between the anodic etching and the deposition of the filler or second layer 608, a thin native oxide layer may form on the walls of the channels through exposure to atmospheric oxygen. The thin oxide layer may not hurt the device because the native oxide layer may be thin and carrier may tunnel through the thin oxide layer. In one embodiment, the solar cell 600, after the first layer 604 has been deposited and etched, may be immersed in a solution containing hydrogen peroxide and ozone to intentionally form a thin oxide layer in a controlled manner and prevent further growth of a native oxide layer.

The thicker the solar cell, the more light that may be collected by the solar cell. A percolated structure shortens the distance that an electron or an electron-hole needs to travel in order to reach the junction. Therefore, a percolated solar cell may be thicker than a planar solar cell. If a percolated solar cell is made sufficiently thick, the distance that an electron or a electron-hole needs to travel in the percolated solar cell may approach or match the distance that an electron or electron-hole needs to travel in a planar solar cell. Thus, a sufficiently thick percolated solar cell may have an efficiency substantially equal to the efficiency of a thinner, planar solar cell, but the thicker, percolated solar call may collect more light. Alternatively, for the same thickness, the percolated solar cell may be more efficient than a planar solar cell due to the shortened distance that electron-holes and electrons travel to reach the junction.

Porous layers may be used in solar cells to shorten the distance to the junction for electrons and electron-holes. By shortening the distance that the electron-holes and electrons need to travel to reach the junction, electrons and electron-holes are less likely to recombine before reaching the junction. Because the electrons and electron-holes are less likely to recombine, more electrons and electron-holes may reach the junction and increase the efficiency of the solar cell.

While the foregoing is directed to embodiments of the present invention, other and further embodiments of the invention may be devised without departing from the basic scope thereof, and the scope thereof is determined by the claims that follow.

1. A solar cell fabrication process, comprising:
forming a first silicon containing layer over a solar cell substrate, the first silicon containing layer having a plurality of openings therein; and
forming a second silicon containing layer over the first silicon containing layer, the second silicon containing layer extending into at least one opening of the first silicon containing layer.

2. The process of claim 1, wherein the first silicon containing layer comprises amorphous silicon.

3. The process of claim 1, wherein the first silicon containing layer comprises microcrystalline silicon.

4. The process of claim 1, wherein forming the first silicon containing layer comprises:
introducing a silicon containing vapor and a poragen forming gas into a processing chamber;
depositing the first silicon containing layer over the substrate, the first silicon containing layer having poragens dispersed therein; and
decomposing the poragens to remove the poragens from the first silicon containing layer and leaving the one or more openings in the first silicon containing layer.

5. The process of claim 4, wherein the poragen is selected from the group consisting of ethylene, propylene, isobutylene, acetylene, allylene, ethylacetylene, 1,3-butadiene, isoprene, 2,3-dimethyl-1,3-butadiene, alpha-terpinine, piperylene, and combinations thereof.

6. The process of claim 4, wherein the decomposing comprises exposing the poragens to an oxygen containing gas and forming a tunnel junction on the walls of the pores.

7. The process of claim 1, wherein forming the first silicon containing layer further comprises:
depositing the first silicon containing layer over the substrate; and
etching the one or more openings into the silicon continuing layer.

8. The process of claim 1, wherein the first silicon containing layer is p-doped silicon.

9. The process of claim 8, further comprising immersing the p-doped silicon layer deposited over the solar cell substrate into a solution comprising hydrogen peroxide and ozone and growing an oxide layer on the p-doped silicon layer.

10. The process of claim 1, wherein the openings are about 0.005 microns to about 0.015 microns wide.

11. A solar cell fabrication process, comprising:
depositing a p-doped silicon layer over a solar cell substrate;
depositing a second layer on the p-doped silicon layer, and creating an uneven interface between the p-doped silicon layer and the second layer such that the second layer extends at least partially into the p-doped silicon layer.

12. The process of claim 11, wherein the p-doped silicon layer is deposited with poragens.

13. The process of claim 12, wherein creating further comprises decomposing the poragens to remove the poragens from the p-doped silicon layer.

14. The process of claim 11, wherein creating comprises anodic etching the p-doped silicon layer.

15. The process of claim 11, wherein the p-doped silicon layer is amorphous.

16. The process of claim 11, wherein the p-doped silicon layer is microcrystalline.

17. The process of claim 11, further comprising immersing the p-doped silicon layer deposited over the solar cell substrate into a solution comprising hydrogen peroxide and ozone and growing an oxide layer on the p-doped silicon layer.

18. A solar cell, comprising:
a first silicon containing layer disposed over a solar cell substrate;
a second silicon containing layer coupled with the first silicon containing layer; and
an interface between the first silicon containing layer and the second silicon containing layer is uneven such that the second silicon containing layer extends at least partially into the first silicon containing layer.

19. The solar cell of claim 18, wherein the first silicon containing layer comprises amorphous silicon.

20. The solar cell of claim 18, wherein the first silicon containing layer comprises microcrystalline silicon.

21. The solar cell of claim 18, wherein the first silicon containing layer comprises p-doped silicon.

22. The solar cell of claim 18, wherein the first silicon containing layer comprises polysilicon.
